(19) United States
(12) Patent Application Publication
(10) Pub. No.: US 2022/0359317 A1
(43) Pub. Date: Nov. 10, 2022

(54) STRESS MEASURING STRUCTURE AND STRESS MEASURING METHOD

(71) Applicant: United Microelectronics Corp., Hsinchu (TW)

(72) Inventors: Yu Hsiang Lin, Hsinchu City (TW); Jing-Yao Kao, New Taipei City (TW); En-Kai Dong, Taipei City (TW)

(73) Assignee: United Microelectronics Corp., Hsinchu (TW)

(21) Appl. No.: 17/342,376

(22) Filed: Jun. 8, 2021

(30) Foreign Application Priority Data
May 10, 2021 (CN) 202110504319.8

(51) Int. Cl. H01L 21/66; G01L 1/00

(52) U.S. Cl. CPC H01L 22/34; G01L 1/00

(57) ABSTRACT

A stress measuring structure, including a substrate, a support layer, a material layer, and multiple marks, is provided. The support layer is disposed on the substrate. The material layer is disposed on the support layer. There is a trench exposing the support layer in the material layer. The material layer includes a main body and a cantilever beam. The trench is located between the cantilever beam and the main body and partially separates the cantilever beam from the main body. One end of the cantilever beam is connected to the main body. The marks are located on the main body and the cantilever beam.

### CROSS-REFERENCE TO RELATED APPLICATION

This application claims the priority benefit of China application no. 202110504319.8, filed on May 10, 2021. The entirety of the above-mentioned patent application is hereby incorporated by reference herein and made a part of this specification.

### BACKGROUND

### Technical Field

The disclosure relates to a measuring structure and a measuring method, and particularly relates to a stress measuring structure and a stress measuring method.

### Description of Related Art

In the current stress measuring method, a material layer to be measured is first formed on a monitoring wafer, and the change in the radius of the monitoring wafer is then measured to obtain the stress of the material layer to be measured. However, the stress measuring method can only measure global stress and cannot measure local stress.

### SUMMARY

The disclosure provides a stress measuring structure and a stress measuring method, which can be used to measure local stress of a material layer to be measured.

The disclosure proposes a stress measuring structure, which includes a substrate, a support layer, a material layer, and multiple marks. The support layer is disposed on the substrate. The material layer is disposed on the support layer. There is trench exposing the support layer in the material layer. The material layer includes a main body and a cantilever beam. The trench is located between the cantilever beam and the main body and partially separates the cantilever beam from the main body. One end of the cantilever beam is connected to the main body. The marks are located on the main body and the cantilever beam.

According to an embodiment of the disclosure, in the stress measuring structure, the cantilever beam may be surrounded by the main body.

According to an embodiment of the disclosure, in the stress measuring structure, the cantilever beam may extend in a first direction. The mark located on the cantilever beam and the mark located on the main body may extend in a second direction and be aligned with each other. The first direction may intersect the second direction.

According to an embodiment of the disclosure, in the stress measuring structure, the first direction may be orthogonal to the second direction.

According to an embodiment of the disclosure, in the stress measuring structure, the marks may be arranged in the first direction and parallel to each other.

According to an embodiment of the disclosure, in the stress measuring structure, the marks arranged in the first direction may have the same width.

According to an embodiment of the disclosure, in the stress measuring structure, the marks arranged in the first direction may have different widths.

According to an embodiment of the disclosure, in the stress measuring structure, multiple spacings between the marks arranged in the first direction may be the same as each other.

According to an embodiment of the disclosure, in the stress measuring structure, multiple spacings between the marks arranged in the first direction may be different from each other.

According to an embodiment of the disclosure, in the stress measuring structure, the marks may be multiple doped regions located in the main body and the cantilever beam or multiple recesses located on a top surface of the main body and a top surface of the cantilever beam.

According to an embodiment of the disclosure, in the stress measuring structure, a top view shape of the trench may be a U shape.

According to an embodiment of the disclosure, in the stress measuring structure, the number of the cantilever beam may be multiple. The cantilever beams may have the same length.

According to an embodiment of the disclosure, in the stress measuring structure, the number of the cantilever beam may be multiple. The cantilever beams may have different lengths.

According to an embodiment of the disclosure, in the stress measuring structure, the number of the cantilever beam may be multiple. The cantilever beams may have the same width.

According to an embodiment of the disclosure, in the stress measuring structure, the number of the cantilever beam may be multiple. The cantilever beams may have different widths.

According to an embodiment of the disclosure, in the stress measuring structure, the stress measuring structure may be located in a chip region or a dicing lane of a product wafer.

The disclosure proposes a stress measuring method, which includes the following steps. A stress measuring structure is provided. The stress measuring structure includes a substrate, a support layer, a material layer, and multiple marks. The support layer is disposed on the substrate. The material layer is disposed on the support layer. There is a trench exposing the support layer in the material layer. The material layer includes a main body and a cantilever beam. The trench is located between the cantilever beam and the main body and partially separates the cantilever beam from the main body. One end of the cantilever beam is connected to the main body. The marks are located on the main body and the cantilever beam. The support layer located between the cantilever beam and the substrate is removed. An offset of the mark located on the cantilever beam is obtained after removing the support layer located between the cantilever beam and the substrate. A stress of the material layer is obtained by the offset of the mark located on the cantilever beam.

According to an embodiment of the disclosure, in the stress measuring method, a method for obtaining the offset of the mark may include measuring a change in a positional relationship between the mark located on the cantilever beam and the mark located on the main body.

According to an embodiment of the disclosure, in the stress measuring method, after removing the support layer located between the cantilever beam and the substrate, the cantilever beam may be suspended above the substrate.

According to an embodiment of the disclosure, in the stress measuring method, after removing the support layer located between the cantilever beam and the substrate, at least a portion of the support layer may remain between the main body and the substrate.

Based on the above, in the stress measuring structure and the stress measuring method proposed by the disclosure, the marks are located on the main body and the cantilever beam. Therefore, after removing the support layer located between the cantilever beam and the substrate, the local stress of the material layer may be obtained by the offset of the mark located on the cantilever beam.

In order for the features and advantages of the disclosure to be more comprehensible, the following specific embodiments are described in detail in conjunction with the accompanying drawings.

### BRIEF DESCRIPTION OF THE DRAWINGS

FIG. 1A is a top view of a stress measuring structure according to an embodiment of the disclosure.

FIG. 1B is a cross-sectional view taken along a section line I-I′ in FIG. 1A according to an embodiment of the disclosure.

FIG. 1C is a cross-sectional view taken along the section line I-I′ in FIG. 1A according to another embodiment of the disclosure.

FIG. 2 is a flowchart of a stress measuring method according to an embodiment of the disclosure.

FIG. 3A is a top view of a stress measuring structure after removing a support layer located between a cantilever beam and a substrate in FIG. 1A.

FIG. 3B is a cross-sectional view taken along a section line I-I′ in FIG. 3A according to an embodiment of the disclosure.

### DETAILED DESCRIPTION OF DISCLOSED EMBODIMENTS

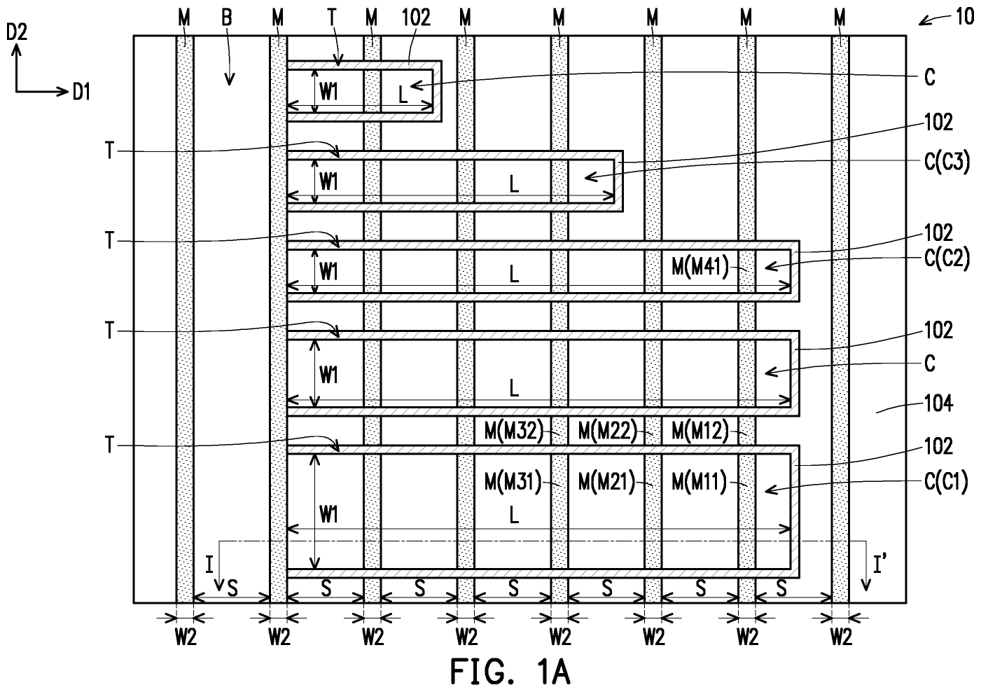

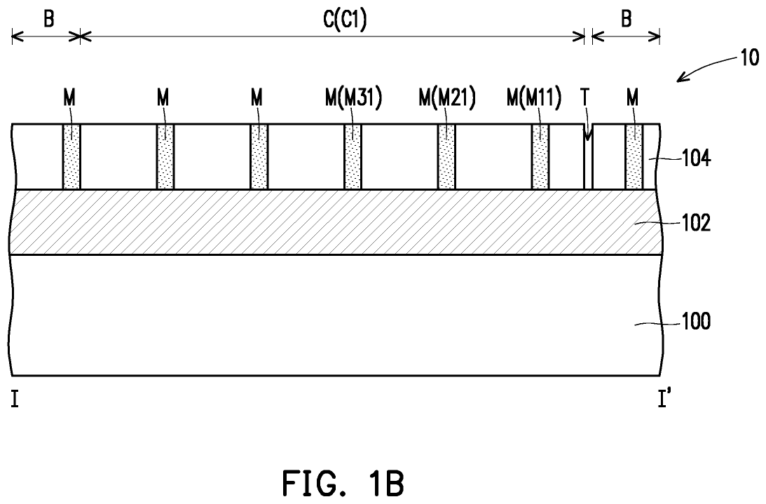

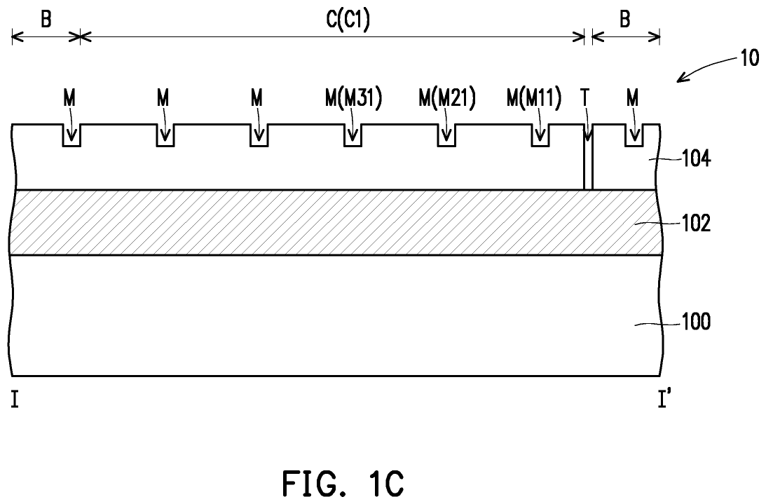

FIG. 1A is a top view of a stress measuring structure according to an embodiment of the disclosure. FIG. 1B is a cross-sectional view taken along a section line I-I′ in FIG. 1A according to an embodiment of the disclosure. FIG. 1C is a cross-sectional view taken along the section line I-I′ in FIG. 1A according to another embodiment of the disclosure.

Please refer to FIG. 1A to FIG. 1C. A stress measuring structure 10 includes a substrate 100, a support layer 102, a material layer 104, and multiple marks M. In some embodiments, the stress measuring structure 10 may be applied to the field of semiconductor or the field of microelectromechanical systems (MEMS). In some embodiments, the stress measuring structure 10 may be located in a chip region or a dicing lane of a product wafer, so that the stress of the material layer 104 to be measured may be measured in real time under the environment of the product wafer. In other embodiments, the stress measuring structure 10 may be located on a monitoring wafer.

The substrate 100 may be a semiconductor substrate, such as a silicon substrate. The support layer 102 is disposed on the substrate 100. The material of the support layer 102 is, for example, oxide (for example, silicon oxide), but the disclosure is not limited thereto.

The material layer 104 is disposed on the support layer 102. The material layer 104 may be a material layer whose stress is to be measured. In this embodiment, the material of the material layer 104 is, for example, polysilicon, but the disclosure is not limited thereto. There is a trench T exposing the support layer 102 in the material layer 104. The top view shape of the trench T may be a U shape. The material layer 104 includes a main body B and a cantilever beam C. The trench T is located between the cantilever beam C and the main body B and partially separates the cantilever beam C from the main body B. One end of the cantilever beam C is connected to the main body B. The cantilever beam C may be surrounded by the main body B. The cantilever beam C may extend in a direction D1. In some embodiments, the material layer 104 including the main body B and the cantilever beam C may be formed by a deposition process, a lithography process, and an etching process, but the disclosure is not limited thereto.

In this embodiment, the number of the cantilever beam C may be multiple, but the disclosure is not limited thereto. As long as the material layer 104 has at least one cantilever beam C, the material layer 104 belongs to the scope of the disclosure. The cantilever beams C may have the same length L or different lengths L. For example, a cantilever beam C1 and a cantilever beam C2 may have the same length L. The cantilever beam C1 and a cantilever beam C3 may have different lengths L. In addition, the cantilever beams C may have the same width W1 or different widths W1. For example, a cantilever beam C1 and a cantilever beam C2 may have different widths W1. The cantilever beam C2 and a cantilever beam C3 may have the same width W1.

The marks M are located on the main body B and the cantilever beam C. In some embodiments, the mark M located on the cantilever beam C and the mark M located on the main body B may extend in a direction D2 and be aligned with each other. For example, a mark M11 located on the cantilever beam C1 and a mark M12 located on the main body B may extend in the direction D2 and be aligned with each other. The direction D1 may intersect the direction D2. In some embodiments, the direction D1 may be orthogonal to the direction D2. The marks M may be arranged in the direction D1 and parallel to each other.

In addition, the marks M arranged in the direction D1 may have the same width W2 or different widths W2. For example, the mark M11 and a mark M21 arranged in the direction D1 may have the same width W2 or different widths W2. In addition, multiple spacings S between the marks M arranged in the direction D1 may be the same as or different from each other. For example, the spacing S between the mark M11 and the mark M21 arranged in the direction D1 and the spacing S between the mark M21 and a mark M31 arranged in the direction D1 may be the same as or different from each other. In this embodiment, the marks M arranged in the direction D2 may have the same width W2. For example, the marks M11 and M12 arranged in the direction D2 may have the same width W2.

In this embodiment, as shown in FIG. 1B, the mark M may be a doped region located in the main body B and the cantilever beam C, but the disclosure is not limited thereto. For example, the mark M (doped region) in FIG. 1B may be formed by performing an ion implantation process on the material layer 104. In other embodiments, as shown in FIG. 1C, the mark M may be a recess located on a top surface of the main body B and a top surface of the cantilever beam C. For example, the mark M (recess) may be formed by patterning the material layer 104 by a photolithography process and an etching process.

In some embodiments, as shown in FIG. 1B and FIG. 1C, although the support layer 102 and the material layer 104 are disposed on only one surface (for example, the front surface) of the substrate 100, the disclosure is not limited thereto. In other embodiments, the support layer 102 and/or the material layer 104 may also be disposed on another surface (for example, the back surface) of the substrate 100.

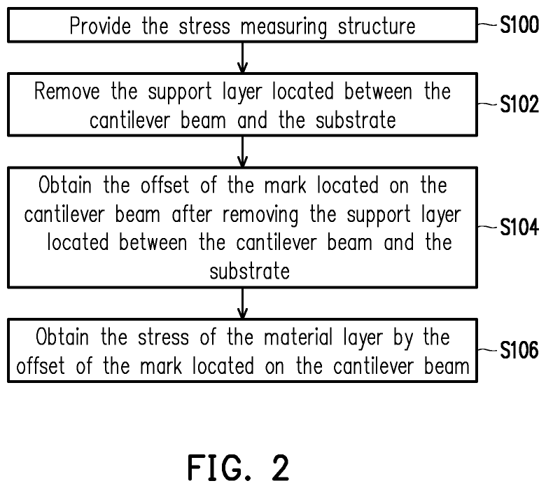

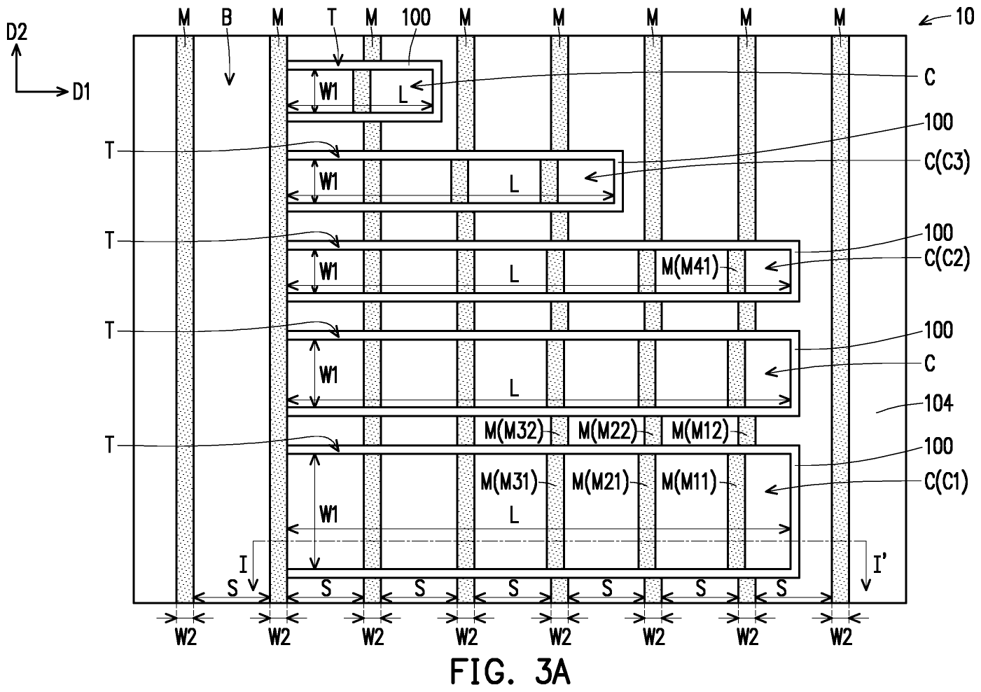

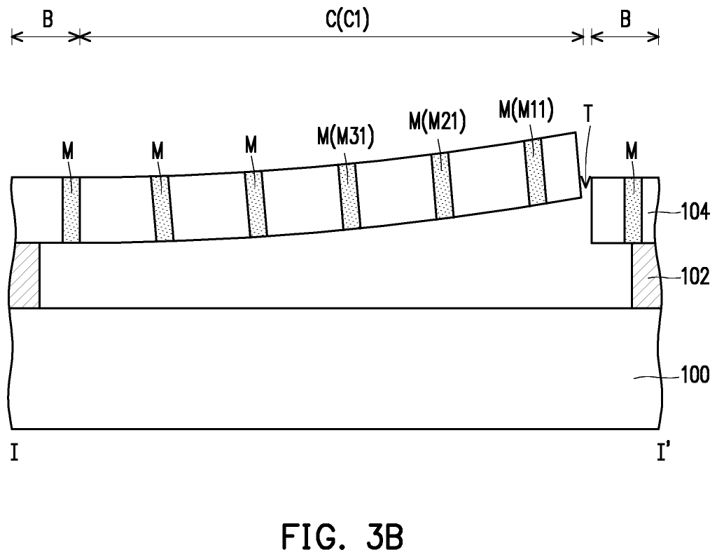

FIG. 2 is a flowchart of a stress measuring method according to an embodiment of the disclosure. FIG. 3A is a top view of a stress measuring structure after removing a support layer located between a cantilever beam and a substrate in FIG. 1A. FIG. 3B is a cross-sectional view taken along a section line I-I′ in FIG. 3A according to an embodiment of the disclosure.

Please refer to FIG. 1A, FIG. 1B, and FIG. 2. In Step S100, the stress measuring structure 10 is provided. Reference may be made to the description of the foregoing embodiment for the detailed content of the stress measuring structure 10, which will not be repeated here.

Please refer to FIG. 2, FIG. 3A, and FIG. 3B. In Step S102, the support layer 102 located between the cantilever beam C and the substrate 100 is removed. After removing the support layer 102 located between the cantilever beam C and the substrate 100, a portion of the substrate 100 may be exposed. As shown in FIG. 3B, after removing the support layer 102 located between the cantilever beam C and the substrate 100, the cantilever beam C may be suspended above the substrate 100. As shown in FIG. 3B, after removing the support layer 102 located between the cantilever beam C and the substrate 100, at least a portion of the support layer 102 may remain between the main body B and the substrate 100. In some embodiments, the support layer 102 exposed by the trench T and the support layer 102 located between the cantilever beam C and the substrate 100 may be removed by an etching process (for example, a wet etching process). For example, when the material of the support layer 102 is silicon oxide, the etchant used in the wet etching process is, for example, diluted hydrofluoric acid (DHF) or buffered oxide etchant (BOE).

As shown in FIG. 3B, after removing the support layer 102 located between the cantilever beam C and the substrate 100, under the influence of the stress of the material layer 104, the cantilever beam C is bent. Depending on the type of the stress, the cantilever beam C may be bent along a direction away from the substrate 100 or a direction toward the substrate 100. In this embodiment, the cantilever beam C is bent along the direction away from the substrate 100 as an example, but the disclosure is not limited thereto.

Please refer to FIG. 2, FIG. 3A, and FIG. 3B. In Step S104, after removing the support layer 102 located between the cantilever beam C and the substrate 100, the offset of the mark M located on the cantilever beam C is obtained. The method for obtaining the offset of the mark M may include measuring the change in the positional relationship between the mark M located on the cantilever beam C and the mark M located on the main body B. In some embodiments, taking the cantilever beam C1 as an example, after removing the support layer 102 located between the cantilever beam C1 and the substrate 100, the marks M11, M21, and M31 located on the cantilever beam C1 are offset (FIG. 3A) due to the bending of the cantilever beam C1. In some embodiments, the offset of the mark M11 may be obtained by measuring the change in the positional relationship between the mark M11 located on the cantilever beam C1 and the mark M12 located on the main body B. In addition, the offset of the mark M21 may be obtained by measuring the change in the positional relationship between the mark M21 located on the cantilever beam C1 and a mark M22 located on the main body B. In addition, the offset of the mark M31 may be obtained by measuring the change in the positional relationship between the mark M31 located on the cantilever beam C1 and a mark M32 located on the main body B.

In some embodiments, the corresponding marks M (for example, the mark M11 on the cantilever beam C1 and a mark M41 on the cantilever beam C2) on the cantilever beams C with different sizes may have the same offset. In some embodiments, due to the influence of the size of the cantilever beam C, since the degree of bending of the cantilever beams C with different sizes is different, the corresponding marks M (for example, the mark M11 on the cantilever beam C1 and the mark M41 on the cantilever beam C2) on the cantilever beams C with different sizes may have different offsets.

Please refer to FIG. 2, FIG. 3A, and FIG. 3B. In Step S106, the stress of the material layer 104 is obtained by the offset of the mark M located on the cantilever beam C. In some embodiments, the stress of the material layer 104 may be obtained by comparing the offset of the mark M located on the cantilever beam C with a database stored with the corresponding relationship between the offset of the mark M and the stress of the material layer 104.

In other embodiments, the stress of the material layer 104 corresponding to the offset of the mark M located on the cantilever beam C may be calculated by a mathematical equation of the corresponding relationship between the offset of the mark M and the stress of the material layer 104.

In other embodiments, the mark M located on the cantilever beam C and the mark M located on the main body B may have the same width W2 and be aligned with each other. The mark M on the main body B may be used as a scale, and the stress of the material layer 104 represented by each scale may be preset. Therefore, the stress of the material layer 104 may be obtained by observing the relationship between the offset of the mark M located on the cantilever beam C and the mark M as the scales located on the main body B. In some embodiments, when the offset of the marks M on the cantilever beam C1 are that the mark M11, the mark M21, and the mark M31 are offset at the same time, it can be known that the stress of the material layer 104 is the stress represented by the mark M32 as the scale on the main body B. In other embodiments, when the offset of the mark M on the cantilever beam C1 is that only the mark M11 on the cantilever beam C1 is offset, it can be known that the stress of the material layer 104 is the stress represented by the mark M12 as the scale on the main body B.

Based on the foregoing embodiments, it can be seen that in the stress measuring structure 10 and the stress measuring method, the marks M are located on the main body B and the cantilever beam C. Therefore, after removing the support layer 102 located between the cantilever beam C and the substrate 100, the local stress of the material layer 104 may be obtained by the offset of the mark M located on the cantilever beam C. In addition, when the stress measuring structure 10 is located in the chip region or the dicing lane of the product wafer, the stress of the material layer 104 to be measured may be measured in real time under the environment of the product wafer. In addition, when the stress measuring structure 10 is located in the chip region or the dicing lane of the product wafer, the stress relationship between the shot to shot, wafer to wafer, or lot to lot of the material layer 104 may be obtained.

In summary, in the stress measuring structure and the stress measuring method of the foregoing embodiments, since the marks are located on the main body and the cantilever beam, the local stress of the material layer may be obtained by the offset of the marks located on the cantilever beam.

Although the disclosure has been disclosed in the foregoing embodiments, the embodiments are not intended to limit the disclosure. Persons skilled in the art may make some changes and modifications without departing from the spirit and scope of the disclosure. The protection scope of the disclosure shall be defined by the appended claims.

What is claimed is:

1. A stress measuring structure, comprising:
a substrate;
a support layer, disposed on the substrate;
a material layer, disposed on the support layer, wherein there is a trench exposing the support layer in the material layer, and the material layer comprises:
a main body; and
a cantilever beam, wherein the trench is located between the cantilever beam and the main body and partially separates the cantilever beam from the main body, and one end of the cantilever beam is connected to the main body; and
a plurality of marks, located on the main body and the cantilever beam.

2. The stress measuring structure according to claim 1, wherein the cantilever beam is surrounded by the main body.

3. The stress measuring structure according to claim 1, wherein
the cantilever beam extends in a first direction,
the mark located on the cantilever beam and the mark located on the main body extend in a second direction and are aligned with each other, and
the first direction intersects the second direction.

4. The stress measuring structure according to claim 3, wherein the first direction is orthogonal to the second direction.

5. The stress measuring structure according to claim 3, wherein the marks are arranged in the first direction and are parallel to each other.

6. The stress measuring structure according to claim 3, wherein the marks arranged in the first direction have a same width.

7. The stress measuring structure according to claim 3, wherein the marks arranged in the first direction have different widths.

8. The stress measuring structure according to claim 3, wherein a plurality of spacings between the marks arranged in the first direction are the same as each other.

9. The stress measuring structure according to claim 3, wherein a plurality of spacings between the marks arranged in the first direction are different from each other.

10. The stress measuring structure of claim 1, wherein the marks comprise a plurality of doped regions located in the main body and the cantilever beam or a plurality of recesses located on a top surface of the main body and a top surface of the cantilever beam.

11. The stress measuring structure according to claim 1, wherein a top view shape of the trench comprises a U shape.

12. The stress measuring structure according to claim 1, wherein a number of the cantilever beam is multiple, and the cantilever beams have a same length.

13. The stress measuring structure according to claim 1, wherein a number of the cantilever beam is multiple, and the cantilever beams have different lengths.

14. The stress measuring structure according to claim 1, wherein a number of the cantilever beam is multiple, and the cantilever beams have a same width.

15. The stress measuring structure according to claim 1, wherein a number of the cantilever beam is multiple, and the cantilever beams have different widths.

16. The stress measuring structure according to claim 1, wherein the stress measuring structure is located in a chip region or a dicing lane of a product wafer.

17. A stress measuring method, comprising:
providing a stress measuring structure, wherein the stress measuring structure comprises:
a substrate;
a support layer, disposed on the substrate;
a material layer, disposed on the support layer, wherein there is a trench exposing the support layer in the material layer, and the material layer comprises:
a main body; and
a cantilever beam, wherein the trench is located between the cantilever beam and the main body and partially separates the cantilever beam from the main body, and one end of the cantilever beam is connected to the main body; and
a plurality of marks, located on the main body and the cantilever beam;
removing the support layer located between the cantilever beam and the substrate;
obtaining an offset of the mark located on the cantilever beam after removing the support layer located between the cantilever beam and the substrate; and
obtaining a stress of the material layer by the offset of the mark located on the cantilever beam.

18. The stress measuring method according to claim 17, wherein a method for obtaining the offset of the mark comprises:
measuring a change in a positional relationship between the mark located on the cantilever beam and the mark located on the main body.

19. The stress measuring method according to claim 17, wherein after removing the support layer located between the cantilever beam and the substrate, the cantilever beam is suspended above the substrate.

20. The stress measuring method according to claim 17, wherein after removing the support layer located between the cantilever beam and the substrate, at least a portion of the support layer remains between the main body and the substrate.
